(19) United States
(12) Patent Application Publication
(10) Pub. No.: US 2025/0151574 A1
(43) Pub. Date: May 8, 2025

(54) DISPLAY APPARATUS

(71) Applicant: LG DISPLAY CO., LTD., Seoul (KR)

(72) Inventor: Seung Won HWANG, Paju-si (KR)

(73) Assignee: LG DISPLAY CO., LTD., Seoul (KR)

(21) Appl. No.: 18/652,171

(22) Filed: May 1, 2024

(30) Foreign Application Priority Data
Nov. 2, 2023 (KR) 10-2023-0150175

(51) Int. Cl. H10K 59/82; H10K 59/90

(52) U.S. Cl. CPC H10K 59/82; H10K 59/90

(57) ABSTRACT

A display apparatus includes a plate; a display panel disposed on the plate; a printed circuit board disposed below the plate; and a circuit film configured to electrically connect the display panel and the printed circuit board. The plate may include an extension part that is bent in a manner corresponding to the bending of the circuit film.

### CROSS-REFERENCE TO RELATED APPLICATION

This application claims the priority of Korean Patent Application No. 10-2023-0150175, filed Nov. 2, 2023, which is hereby incorporated by reference in its entirety.

### BACKGROUND

### Field of the Disclosure

The present disclosure relates to a display apparatus.

### Description of the Background

As society has entered the full-fledged information age, various display apparatuses have been developed to process and display a large amount of information. There are various types of display apparatuses that display images, such as liquid crystal display apparatuses, organic light emitting display apparatuses, and inorganic light emitting display apparatuses.

The applications for display apparatuses are becoming increasingly diverse, including not only personal portable devices, computer monitors, and televisions, but also automotive display apparatuses.

### SUMMARY

Since a circuit film connected to a display panel in a display apparatus is bent, flexible, and thin, various types of researches are being conducted to improve the crack fault of the circuit films. If a crack occurs in the connection portion of a circuit film in the display apparatus, the reliability of the display apparatus may be affected, resulting in a problem with the performance of the display apparatus.

Therefore, the present disclosure is to provide a novel display apparatus capable of improving the reliability of the display apparatus and capable of improving the crack fault of the connection portion of the circuit film in the display apparatus.

In addition, the present disclosure is to provide a display apparatus having improved reliability and preventing a driving error by improving the crack fault of the circuit film connected to the display panel.

Problems according to an aspect of the present disclosure are not limited to the above-mentioned problems, and other problems which are not mentioned will be clearly understood by those skilled in the art from the following disclosure.

A display apparatus according to an aspect of the present disclosure may include a plate; a display panel disposed on the plate; a printed circuit board electrically connected to one side of the display panel; and at least one circuit film having one side and the other side electrically connected to the display panel and the printed circuit board, respectively, at least a portion of which is bent toward a rear surface of the display panel, wherein at least a portion of the plate includes at least one extension part that is configured to overlap the circuit film on the rear surface of the circuit film and to protrude from a side surface of the display panel.

Specific details of the other aspects are set forth in the detailed description and drawings.

According to an aspect of the present disclosure, the inclusion of an extension part of the plate applied to the display apparatus may prevent the occurrence of the crack in the connecting portion of the circuit film to avoid a driving error, thereby providing the low-power display apparatus with an improved lifespan.

According to an aspect of the present disclosure, since the plate applied to the display apparatus overlaps a driving chip, heat generated by the driving chip may be dissipated through the plate, thereby providing the display apparatus that improves the driving fault of the driving chip due to high temperature.

According to an aspect of the present disclosure, the plate applied to the display apparatus may enable fixing and supporting the circuit film and the printed circuit board, thereby providing the display apparatus with improved reliability capable of replacing a separate guide holder and preventing the circuit film from flowing and cracking.

The effects of this disclosure are not limited to the above effects, and other effects, which are not mentioned herein, will be obvious to those skilled in the art from the following description.

The scope of the claims is not limited by the content of the description of the disclosure because the content of the disclosure as described in the problem to be solved, means for solving the problem, and effect described above does not specify the essential features of the claims.

### BRIEF DESCRIPTION OF THE DRAWINGS

The above and other features and advantages of the present disclosure will become more apparent to those of ordinary skill in the art by describing exemplary aspects thereof in detail with reference to the attached drawings, in which:

FIG. 1 is an exploded perspective view illustrating a display apparatus according to one aspect of the present disclosure;

FIG. 2 is a rear view of the display apparatus wherein some components are omitted from FIG. 1;

FIG. 3 is a cross-sectional view taken along line A-A′ in FIG. 2;

FIG. 4 is a plan view illustrating a plate of a display apparatus according to an aspect of the present disclosure;

FIG. 5 is a diagram illustrating a display apparatus according to another aspect of the present disclosure;

FIG. 6 is a plan view illustrating a display apparatus according to an aspect of the present disclosure;

FIG. 7 is a cross-sectional view of a display panel taken along line B-B′ in FIG. 6 according to an aspect of the present disclosure; and

FIG. 8 is a diagram illustrating an example of the use of a display apparatus according to an aspect of the present disclosure.

### DETAILED DESCRIPTION

Advantages and features of the present disclosure, and methods of achieving them will become apparent with reference to various aspects, which are described in detail, in conjunction with the accompanying drawings. However, the present disclosure is not limited to the aspects to be described below and may be implemented in different forms, the aspects are only provided to completely disclose the present disclosure and completely convey the scope of the present disclosure to those skilled in the art, and the present disclosure is defined by the disclosed claims.

Since the shapes, sizes, proportions, angles, numbers, and the like disclosed in the drawings for describing the aspects of the present disclosure are only exemplary, the present disclosure is not limited to the illustrated items. The same reference numerals indicate the same components throughout the disclosure. Further, in describing the present disclosure, when it is determined that a detailed description of related known technology may unnecessarily obscure the gist of the present disclosure, the detailed description thereof will be omitted. When ‘including,’ ‘having,’ ‘consisting,’ and the like mentioned in the present disclosure are used, other parts may be added unless ‘only’ is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ next to, and the like, one or more other parts may be located between the two parts unless ‘immediately’ or ‘directly’ is used.

When describing a temporal contextual relationship is described, such as “after,” “following,” “next to,” or “before,” it may also include non-contiguous cases unless “immediately” or “directly” is used.

The first, the second, and so on are used to describe various components, but these components are not limited by these terms. These terms are used only to distinguish one component from another. Therefore, the first component referred to below may be a second component within the technical spirit of the present disclosure.

Terms such as first, second, A, B, (a), (b), and the like may be used to describe elements of the aspects of the present disclosure. Such terms are intended only to distinguish one component from another and are not intended to define the nature, sequence, order, or number of such components. When a component is described as “connected,” “coupled,” or “attached” to another component, it is to be understood that the component may be directly connected or attached to the other component, but that there may also be other components “interposed” between the respective components which may be indirectly connected or attached where not specifically stated.

It should be understood that the term “at least one” includes all possible combinations of one or more related components. For example, the meaning of “at least one of the first, second, and third components” includes not only the first, second, or third component, but also any combination of two or more of the first, second, and third components.

As used herein, “a display apparatus” may include a display apparatus in a narrow sense, such as a liquid crystal module (LCM), an organic light-emitting diode (OLED) module, or a quantum dot (QD) module, which includes a display panel and a driver for driving the display panel. It may also include a set electronic apparatus or a set device or set apparatus, such as a laptop computer, a television set, a computer monitor, an automotive display apparatus or an equipment display apparatus including another form in a vehicle, and a mobile electronic apparatus, such as a smart phone or an electronic pad, which is a complete product or finished product including the LCM, the OLED module, and the QD module.

Accordingly, the display apparatus as described herein may include a display apparatus itself in the narrow sense, such as the LCM, the OLED module, and the QD module, and an application product, as well as a set device, an end user device that includes the LCM, the QLED module, and the QD module.

In some cases, the LCM, the OLED module, and the QD module comprising the display panel and the driver may be expressed as a “display apparatus” in the narrow sense, while the electronic device as a finished product including the LCM, the OLED module, and the QD module may be expressed as a “set device”. For example, the display apparatus in the narrow sense may include a liquid crystal display (LCD) panel, an organic light-emitting diode (OLED) display panel, or a quantum dot (QD) display panel and a source PCB that is a control part for driving the display panel, and the set device may further include a set PCB that is a set control part electrically connected to the source PCB to control the entire set device.

A display panel used in an aspect of the present disclosure may be any type of display panels, including liquid crystal display panels, organic light-emitting diode (OLED) display panels, quantum dot (QD) display panels, and electroluminescent display panels. The display panel of this aspect is a flexible substrate for the OLED display panel and an underlying backplate support structure that allows for bezel bending, but is not limited to any particular display panel. Furthermore, the display panel used in the display apparatus according to an aspect of the present disclosure is not limited to the shape or size thereof.

For example, when the display panel is an OLED display panel, it may include a plurality of gate lines and data lines, and pixels formed at the intersection of the gate lines and/or the data lines. In addition, it may comprise an array including thin-film transistors, which are elements for selectively applying a voltage to each pixel, a light-emitting element layer on the array, and an encapsulation substrate or an encapsulation layer disposed on the array to cover the light-emitting element layer. The encapsulation layer may protect the thin-film transistors and the light-emitting element layer from external impact and prevent moisture or oxygen from penetrating into the light-emitting element layer. In addition, the layer formed on the array may include an inorganic light-emitting layer, for example, a nano-sized material layer or quantum dot.

Each of the features of the various aspects described herein may be coupled or combined with one another in whole or in part, and may be technologically interlocked and operated in various ways, and each of the aspects may be carried out independently or in conjunction with one another.

Hereinafter, aspects of the present disclosure are illustrated by way of the accompanying drawings and examples. The dimensions of the components shown in the drawings are to scale for illustrative purposes only and are not to scale with the actual components shown in the drawings.

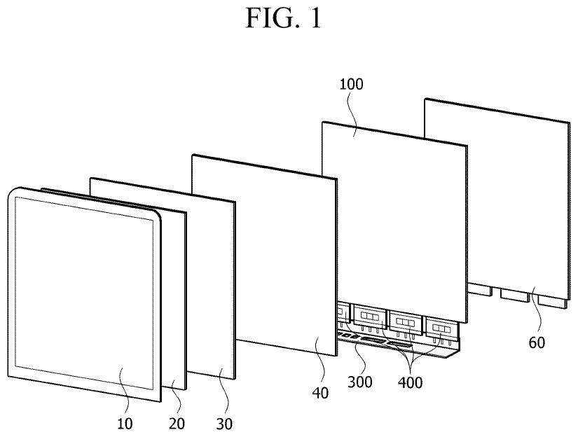

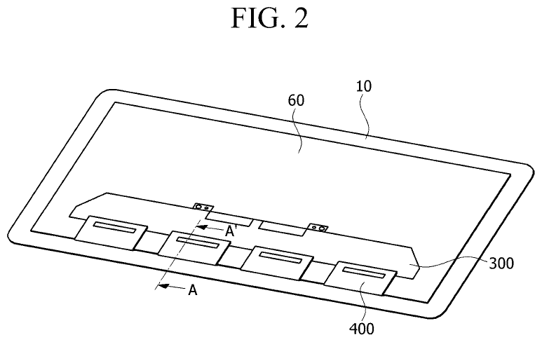

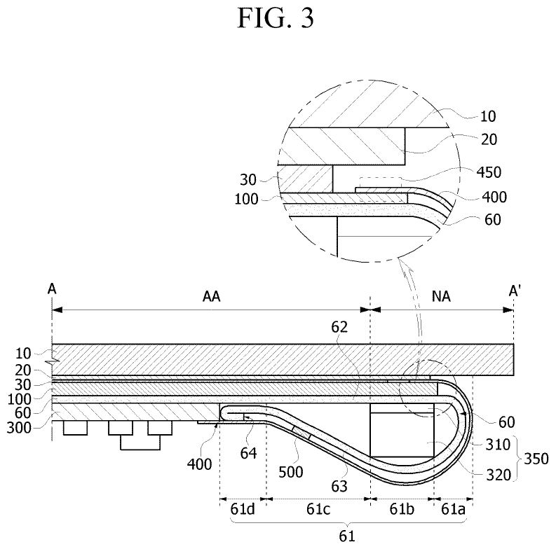

FIG. 1 is an exploded perspective view illustrating a display apparatus according to one aspect of the present disclosure. FIG. 2 is a rear view of the display apparatus, wherein some components are omitted from FIG. 1. FIG. 3 is a cross-sectional view of a display apparatus according to one aspect of the present disclosure. FIG. 3 is a cross-sectional view taken along line A-A′ in FIG. 2.

A display apparatus according to an aspect of the present disclosure may be mounted on a vehicle, for example, to provide a driver and passengers of the vehicle with a video or image necessary for the driving of the vehicle. However, it may not be limited to this use and may also be used when it is carried by the user without being mounted on the vehicle. The following describes a display apparatus that is mounted, for example, on a vehicle, in accordance with an aspect of the present disclosure. The display apparatus mounted on a vehicle is one example for illustrating the present disclosure, and aspects of the present disclosure are not limited thereto.

Referring now to FIGS. 1 to 3, a display apparatus according to an aspect of the present disclosure may include a display panel 100, a plate 60 on a rear surface of the display panel 100, a printed circuit board (PCB) 300 electrically coupled to the display panel 100, and a circuit film 400.

A video or an image may be reproduced on the display panel 100. The reproduced video or image may be, for example, navigation information necessary for driving, an image captured by a camera mounted on a vehicle, or various other contents needed by a driver or a passenger. Aspects of the present disclosure are not limited to those described above.

The printed circuit board 300 may be electrically coupled to the display panel 100. The printed circuit board 300 may include a device for communicating with an external device such as a camera or a main control module of a vehicle and a device for driving the display panel 100 to reproduce a video or image, may be provided with internal circuitry, and may include various other active and passive elements.

One side of the circuit film 400 may be electrically connected to the display panel 100, and the other side thereof may be electrically connected to the printed circuit board 300. A portion of the circuit film 400 may be disposed bent toward the rear surface of the display panel 100. FIG. 1 illustrates an example of the circuit film 400 in an unfolded state.

The circuit film 400 may be formed of a flexible material that is thin and bendable. The circuit film 400 may electrically connect the display panel 100 and the printed circuit board 300. For example, the circuit film 400 may be provided with various active and passive elements, and may be provided with a driving circuit to drive the display panel 100.

The driving circuit to drive the display panel 100 may also be arranged to be distributed on the printed circuit board 300 and the circuit film 400. Referring to FIG. 3, the circuit film 400 may be provided with a driving chip 500 that forms at least a portion of the driving circuit for the display panel 100. There may be a plurality of circuit films 400. Referring to FIG. 2, at least one circuit film 400 may be arranged at a distance from each other.

The display apparatus according to an aspect of the present disclosure may further include a cover member 10, a first adhesive member 20, a functional film 30, and a second adhesive member 40 on the top side of the display panel 100 in order. The plate 60 may be included under the display panel 100 as a support structure. The components included in the display apparatus may be formed in a thin shape to create a slim display panel.

The cover member 10 may be disposed in front of the display panel 100 to protect the display panel 100. The cover member 10 may be formed of a transparent material, so that light irradiated from the cover member 10 may pass through the cover member 10.

In an aspect, the functional film 30 may include a wide-angle adjustment structure for adjusting a visible range of an image displayed on the display panel 100. The wide-angle adjustment structure may be provided within the functional film 30 in a trapezoidal pattern in which the angle, when viewed in cross-section, is adjusted to match a desired visible range. The trapezoidal pattern may be formed of a light-shielding material, and aspects of the present disclosure are not limited thereto. For example, the functional film 30 may also include a polarizer or the like to control display characteristics (e.g., external light reflection, color accuracy, luminance, etc.). In some cases, the functional film 30 may be incorporated in a pattern on the top surface of the display panel 100 or the inner surface of the cover member 10 without being separately configured. Aspects of the present disclosure are not limited thereto. The first adhesive member 20 may be disposed between the cover member 10 and the functional film 30. One surface of the first adhesive member 20 may be adhered to the cover member 10 and the other surface may be adhered to the functional film 30, thereby adhering the functional film 30 to the cover member 10.

For example, the second adhesive member 40 may be disposed between the functional film 30 and the display panel 100. One surface of the second adhesive member 40 may be adhered to the functional film 30 and the other surface may be adhered to the display panel 100, thereby allowing the functional film 30 to be adhered to the display panel 100. In an aspect, the second adhesive member 40 may be disposed between the cover member 10 and the display panel 100.

The first adhesive member 20 and the second adhesive member 40 may be formed of a transparent material with good adhesion, such as an optically clear adhesive (OCA), a pressure sensitive adhesive (PSA), or an optically clear resin (OCR). The aspect of the present disclosure is not limited thereto.

For example, the plate 60 may be disposed at the rear surface of the display panel 100. For example, the plate 60 may serve as a heat sink that cools the display panel 100 by dissipating heat generated from the display panel 100 to the outside. Aspects of the present disclosure are not limited to those described above.

The plate 60 may be made of a metal sheet that is easily fabricated by sheet metal processing, has a high heat transfer rate (thermal conductivity), and has excellent resistance, for example, aluminum (Al), copper (Cu), or the like. Alternatively, the plate 60 may be made of a graphite material. In other words, the plate 60 may be a metal sheet of aluminum (Al), copper (Cu) or a graphite sheet, which has a bent shape. Aspects of the present disclosure are not limited to those described above.

FIG. 2 is a rear view of the display apparatus wherein some components such as the adhesive member and the like are omitted from FIG. 1 for ease of description. For example, FIG. 2 is a plan view illustrating the circuit film 400 of FIG. 1 in a bent state.

FIG. 3 is a cross-sectional view taken along line A-A′ in FIG. 2. Referring to FIGS. 2 and 3, the circuit film 400 may be bendable. For example, one side of the circuit film 400 may be connected to the display panel 100 and the other side may be connected to the printed circuit board 300. One side of the circuit film 400 may be electrically connected to the display panel 100. The other side of the circuit film 400 may be electrically connected to the printed circuit board 300. As the circuit film 400 is bent, the other side of the circuit film 400 and the printed circuit board 300 may be disposed on the rear surface of the display panel 100. For example, the at least one circuit film 400 may be formed of a thin and flexible material that is bendable. At least a portion of the at least one circuit film 400 may be bendable. For example, the circuit film 400 may be bent to allow the printed circuit board 300 to be electrically connected to one side of the display panel 100. Referring to FIG. 3, in accordance with an aspect of the present disclosure, the display apparatus may further include a driving chip 500, and the driving chip 500 may be on the circuit film 400.

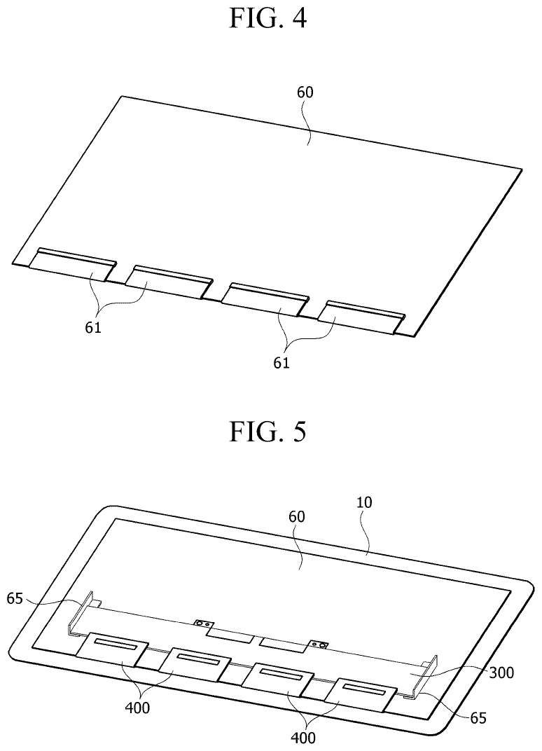

FIG. 4 is a plan view illustrating a plate of a display apparatus according to an aspect of the present disclosure.

FIG. 5 is a rear view of a display apparatus including a plate according to another aspect of the present disclosure.

Referring to FIGS. 3 and 4, according to an aspect, the plate 60 may include at least one extension part 61 that protrudes from a side surface of the display panel 100. For example, the extension part 61 of the plate 60 may overlap the circuit film 400 on the rear surface of the circuit film 400 in a non-display area of the display apparatus. For example, the circuit film 400 may be bent toward the rear surface of the display panel 100. For example, the extension part 61 of the plate 60 may be bent from one side of the plate 60 toward the rear surface of the display panel 100. For example, the circuit film 400 and the extension part 61 of the plate 60 may be bent in the same direction. For example, the extension part 61 of the plate 60 may support (or guide) the circuit film 400 to prevent the connection portion 450 of the circuit film 400, which is thin, from cracking. For example, even though an external force is applied to the attachment area of the display panel 100 and the circuit film 400, which is flexible, due to a collision or the like during transportation or movement of a display apparatus module or product, the extension part 61 of the plate 60 may prevent one side of the circuit film 400 from separating from the display panel 100. For example, it may be possible to prevent a driving fault by preventing a circuit connection fault. Aspects of the present disclosure are not limited to those described above.

For example, the at least one extension part 61 of the plate 60 may be bent from one side of the plate 60 toward the rear surface of the display panel 100. For example, the display panel 100 may have a driving chip 500 on its rear surface. The driving chip 500 may be, for example, a drive integrated circuit chip (DIC). For example, the driving chip 500 may be disposed between the circuit film 400 and the plate 60. Aspects of the present disclosure are not limited to those described above.

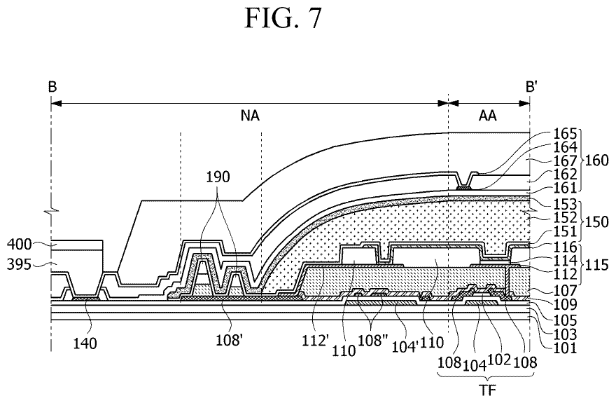

Referring to FIG. 3, when an external force is applied, for example, due to a collision or the like during transportation of a display apparatus module, the connection portion 450 between the circuit film 400 and the display panel 100 may not be smoothly connected, resulting in electrical signal fault due to damage to the pad 140 (see FIG. 7) of the display panel 100. For example, the plate 60 may include the at least one extension part 61 that protrudes from the side and rear surfaces of the display panel 100. For example, the extension part 61 of the plate 60 may support and guide the thin circuit film 400. For example, a driving fault of a display screen may be avoided by preventing a short circuit at the connection portion 450 where the thin circuit film 400 and the display panel 100 are connected. For example, the plate 60 may overlap at least partially with the circuit film 400. For example, the extension part 61 of the plate 60 may be replaced with a guide holder to guide the circuit film 400 and/or the printed circuit board 300.

For example, the extension part 61 of the plate 60 may include a first region 61a, a second region 61b, a third region 61c, and a fourth region 61d.

In an aspect, the extension part 61 of the plate 60 may protrude outwardly from the first region 61a toward the outer periphery of the display panel 100. Aspects of the present disclosure are not limited to those described above.

In an aspect, the plate 60 may include an upper layer 62 and a lower layer 63 formed by a hemming process of bending and pressing a metal. For example, the plate 60 may be hemmed so that at least a portion of the upper layer 62 and at least a portion of the lower layer 63 of the plate 60 face each other. The display panel 100 may be supported by the upper layer 62 of the plate 60, and the circuit film 400 and/or the printed circuit board 300 may be supported by the lower layer 63 of the plate 60. For example, there may be a difference between the thickness of the plate 60 and the thickness of the printed circuit board 300, so that an end portion that is at least a portion of the extension part 61 may be bent using a hemming process to form a bent portion 64, and the bent portion 64 may be used to support the circuit film 400 and/or the printed circuit board 300. For example, the plate 60 may include an extension part 61 that is bent in a manner corresponding to the bending of the circuit film 400.

In an aspect, the extension part 61 of the plate 60 may overlap the cushion member 350 in the second region 61b. For example, the cushion member 350 may be disposed between the upper layer 62 and the lower layer 63 of the plate 60, and may include a foam tape or a foam pad. The cushion member 350 may prevent the upper layer 62 and lower layer 63 of the plate 60 from being pressed, impacted, or the like. The cushion member 350 may have a shock absorbing function, which may mitigate impact, compression, etc. of various components that may come into contact with the plate 60. At least a portion of the cushion member 350 may be in contact with the extension part 61 of the plate 60. For example, the cushion member 350 may be a cushion layer, but is not limited to such terminology. For example, the cushion member 350 may include a material such as an epoxy-based or acrylic-based polymer or resin. Aspects of the present disclosure are not limited to those described above. For example, the cushion member 350 may include a foam 320 and a third adhesive member 310. For example, the plate 60 and the foam 320 may be adhered or fixed to each other by the third adhesive member 310. The third adhesive member 310 may be made of at least one layer of at least one materials that are transparent with good adhesion, such as a transparent optical clear adhesive (OCA), a transparent optical clear resin (OCR), or a pressure sensitive adhesive (PSA). Aspects of the present disclosure are not limited to those described above.

In an aspect, the extension part 61 of the plate 60 may overlap the driving chip 500 at the third region 61c. For example, the extension part 61 of the plate 60 may be in contact with the driving chip 500 at the third region 61c. The driving chip 500 may be disposed between the lower layer 63 of the plate 60 and the circuit film 400. For example, when the plate 60 is in contact with the driving chip 500, the extension part 61 of the plate 60 disposed on the driving chip 500 may effectively radiate and dissipate (emit) a large amount of heat caused by driving the driving chip 500. For example, it may be effective for heat dissipation when exposed to high-temperature environments, such as in automotive display apparatuses. Aspects of the present disclosure are not limited to those described above.

In an aspect, the extension part 61 of the plate 60 may be fixed in the first direction by contacting an end of the printed circuit board 300 at the fourth region 61d. At least a portion of the extension part 61 of the plate 60 may contact at least a portion of the printed circuit board 300. In an aspect, the extension part 61 of the plate 60 may be bent at the fourth region 61d to hold the printed circuit board 300 in place even when it is shaken due to movement during transportation (or movement). For example, with reference to FIGS. 3 and 4, the extension part 61 of the plate 60 may serve as a stopper to support one side of the printed circuit board 300 when assembling the printed circuit board 300. Accordingly, the extension part 61 of the plate 60 may prevent the printed circuit board 300 from moving outwardly relative to the first direction, for example, the Y-axis direction. For example, the outward direction may mean the direction from the center to the edge of the display apparatus.

For example, when the printed circuit board 300 is not fixed, the printed circuit board 300 may be misaligned due to work deviations based on the mounting position of the printed circuit board 300 to deform the shape of the circuit film 400, which may cause tensile or compressive tension to be applied to the connection portion 450 of the circuit film 400 to cause the occurrence of the crack. For example, the end of the lower layer 63 of the plate 60 may be in contact with at least a portion of the upper layer 62 in the fourth region 61d. Aspects of the present disclosure are not limited to those described above.

For example, the thickness of the printed circuit board 300 may be greater than or equal to 0.6 mm and less than or equal to 1.0 mm. The thickness of the plate 60 may be greater than or equal to 0.3 mm and less than or equal to 0.5 mm. Since the thickness of the printed circuit board 300 may be thicker than the thickness of the plate 60, the end of the plate 60 in the fourth region 61d may be thicker or bent to effectively fix the printed circuit board 300.

Referring to FIG. 5, in an aspect, the side surface ends of the plate 60 may include protrusions 65. The protrusions 65 of the plate 60 may hold the printed circuit board 300 in a second direction perpendicular to the first direction. For example, the plate 60 may include the protrusions 65 in regions that overlaps ends of the printed circuit board 300. The extension part 61 and the protrusions 65 of the plate 60 may fix the printed circuit board 300 and prevent the circuit film 400 from cracking due to shaking, thereby preventing the driving fault of the display apparatus. For example, driving faults may be prevented in shaky, high-temperature environments, such as those found in automotive display apparatuses.

For example, at least one, e.g., two, protrusions 65 may be formed to protrude from the rear surface of the plate 60. The two protrusions 65 may be spaced apart from each other such that they have a predetermined spacing. In addition, the two protrusions 65 may guide the arrangement of the printed circuit board 300 such that the printed circuit board 300 is disposed between the two protrusions 65. For example, the protrusions 65 may be formed in the second direction perpendicular to the first direction, such as an X-axis direction.

In an aspect, the protrusions 65 may protect the printed circuit board 300 from external impact. For example, the protrusions 65 may be integrally formed with the plate 60.

Referring now to FIGS. 3 and 4, for example, at least one extension part 61 of the plate 60 may be a plurality of extension part, which are spaced apart from each other. The number of the extension parts 61 of the plate 60 according to an aspect of the present disclosure may be the same as the number of the circuit films 400. For example, the at least one extension part 61 of the plate 60 may overlap the at least one circuit film 400. For example, at least a portion of the plate 60 may be in at least partial contact with the at least one circuit film 400. For example, the at least one extension part 61 of the plate 60 may be in at least partial contact with the at least one circuit film 400. For example, the extension parts 61 of the plate 60 may be disposed on the rear surface of the circuit film 400 in one-to-one correspondence. Aspects of the present disclosure are not limited to those described above.

For example, there may be a region where the extension parts 61 of the plate 60 are not spaced apart, but are combined in one so as not to overlap the circuit film 400.

For example, the number of the at least one extension part 61 of the plate 60 may be different from the number of the at least one film 400. The number of the circuit films 400 and/or the number of the extension parts 61 of the plate 60 shown in the drawings according to an aspect of the present disclosure is merely an example, and aspects of the present disclosure are not limited thereto.

For example, a material of the plate 60 may be different from a material of the circuit film 400. The plate 60 may be made of a material that is easily fabricated by sheet metal processing, has a high heat transfer rate (thermal conductivity), and has excellent resistance, for example, aluminum material. Aspects of the present disclosure are not limited to those described above. The plate 60 of the display apparatus according to an aspect of the present disclosure may include a heat-dissipating metal, such as aluminum or an aluminum alloy, as a base layer, and a coating layer on the base layer. The material of the circuit film 400 may include, for example, polyimide (PI). Aspects of the present disclosure are not limited to those described above.

For example, the thickness of the plate 60 may be different from the thickness of the circuit film 400. For example, the plate 60 may be thicker than the thickness of the circuit film 400 connecting the printed circuit board 300 and the display panel 100 because it supports the display panel 100 and has the function of heat dissipation. For example, the plate 60 may be configured to be thicker than the display panel 100 to provide a support function and a heat dissipation function. The thickness of the plate 60 may be 0.2 mm or more and 1 mm or less. Aspects of the present disclosure are not limited to those described above. For example, the circuit film 400 may be formed of a flexible material that is thin and bendable. The thickness of the circuit film 400 may be configured to be 0.01 mm or more and 0.1 mm or less. Aspects of the present disclosure are not limited to those described above.

The circuit film 400 of the display apparatus according to an aspect of the present disclosure may be formed of a thin and flexible material, allowing the display panel 100 and the printed circuit board 300 to be electrically connected upon bending.

In an aspect, the thin circuit film 400 may have a predetermined elasticity due to its material. Accordingly, a predetermined tension may be applied to the circuit film 400, which in turn applies a predetermined stress to the connection portion 450. For example, since a predetermined tension is applied to the circuit film 400, damage to the circuit film 400 may easily occur when a predetermined load is additionally applied to the circuit film 400. For example, if a stress in excess of the yield stress is applied to the connection portion 450, which in turn applies a predetermined load to the circuit film 400, damage to or separation of the circuit film 400 may occur in the connection portion 450.

The display apparatus according to an aspect of the present disclosure may prevent the circuit film 400 from separating from the display panel 100 by supporting the circuit film 400 against the predetermined load applied to the circuit film 400 using the extension part 61 of the plate 60, which is bendable. For example, the extension part 61 may guide the bending of the circuit film 400. For example, the plate 60 and the extension part 61 may be integrally formed.

For example, the end of the extension part 61 in a folded or bent state by a hemming process may stably support the printed circuit board 300, thereby preventing the printed circuit board 300 from moving in the first direction. For example, the bent end of the extension part 61 may be referred to as the bent portion 64, and one side of the circuit film 400 may be supported by the bent portion 64 even if the plate 60 has a smaller thickness than the printed circuit board 300.

The display apparatus according to an aspect of the present disclosure may use the cushion member 350 that is attached between the upper layer 62 and the lower layer 63 of the plate 60 to allow the cushion member to absorb loads in excess of the yield stress applied to the extension part 61 of the plate 60.

The display apparatus according to an aspect of the present disclosure may prevent the printed circuit board 300 from moving in the second direction by using the protrusions 65 that support the opposite ends of the printed circuit board 300 in the second direction, while protecting the printed circuit board 300 from impact in the second direction.

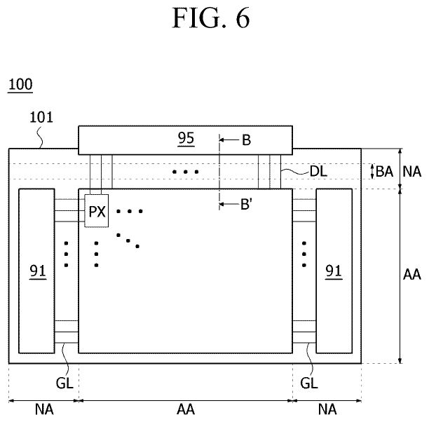

FIG. 6 is a plan view illustrating a display apparatus according to an aspect of the present disclosure.

The display apparatus according to an aspect of the present disclosure may include the display panel 100. The display panel 100 may include a display area AA arranged on the substrate 101 and a non-display area NA arranged around the display area AA.

For example, the material of the substrate 101 may be glass. For example, the substrate 101 may be formed of a plastic material having the flexibility to allow for bending. For example, the substrate 101 may be made of materials such as PI (polyimide), PET (polyethylene terephthalate), PEN (polyethylene naphthalate), PC (polycarbonate), PES (polyethersulfone), PAR (polyarylate), PSF (polysulfone), and COC (cyclio-olefin copolymer), but aspects of the present disclosure are not limited thereto. In another aspect of the present disclosure, the substrate 101 may be made of a semiconductor material, such as a silicon wafer or the like.

The display area AA may be an area in which a plurality of sub-pixels PX are disposed to display an image. Each of the plurality of sub-pixels PX may be an individual unit that emits light. A light-emitting element and a driving circuit may be disposed in each of the plurality of sub-pixels PX. For example, a display element for displaying an image and a circuit part for driving the display element may be disposed in the plurality of sub-pixels PX. For example, when the display apparatus is an organic light emitting display apparatus, the display element may include an organic light-emitting element, and when the display apparatus is a liquid crystal display apparatus, the display element may include a liquid crystal element. The plurality of sub-pixels PX may include, but are not limited to, a red sub-pixel PX, a green sub-pixel PX, a blue sub-pixel PX, and/or a white sub-pixel PX.

The non-display area NA may be an area where no image is displayed. The non-display area NA may be an area in which various wirings and driving ICs for driving the plurality of sub-pixels PX disposed in the display area AA are disposed. For example, at least one of the data driver 95 and the gate driver 91 may be disposed in the non-display area NA, and aspects of the present disclosure are not limited to those described above.

The non-display area NA may be the area surrounding the display area AA. For example, the non-display area NA may be located around the display area AA. For example, the non-display area NA may be an area extending from the display area AA, or may be an area in which the plurality of sub-pixels PX are not disposed, and aspects of the present disclosure are not limited to those described above.

The non-displayed area NA where no image is displayed may be a bezel area, or may further include a bending area BA where the substrate 101 is bent, and aspects of the present disclosure are not limited to those described above.

A plurality of data lines DL and a plurality of gate lines GL may be arranged in the display area AA. For example, a plurality of data lines DL may be arranged in rows or columns, and a plurality of gate lines GL may be arranged in columns or rows. A sub-pixel PX may be disposed in an area formed by the data line DL and/or the gate line GL.

The sub-pixel PX of the display area AA may include a thin-film transistor including a semiconductor layer. For example, the thin-film transistor may include an oxide semiconductor material, and aspects of the present disclosure are not limited to those described above. For example, the thin-film transistor may be a transistor, but is not limited to such terminology.

According to an aspect of the present disclosure, a gate driver 91 including a gate driving circuit may be disposed in the non-display area NA. The gate driving circuit of the gate driver 91 may sequentially drive each row of pixels in the display area AA by sequentially supplying scan signals to the plurality of gate lines GL. For example, a row of pixels may be a row of pixels connected to a single gate line. The gate driving circuit may also be referred to as scan driving circuit, but is not limited to such terminology.

According to an aspect of the present disclosure, the gate driver 91 may be configured to have bilateral symmetry on opposite sides of the display area AA, but aspects of the present disclosure are not limited thereto. For example, the gate driver 91 may include a scan driver and/or an EM driver.

The gate driving circuit may comprise a thin-film transistor having a polycrystalline semiconductor layer, may comprise a thin-film transistor having an oxide semiconductor layer, or may comprise a pair of a thin-film transistor having a polycrystalline semiconductor layer and a thin-film transistor having an oxide semiconductor layer. It may be configured simultaneously in the same process when the same semiconductor material is used for the thin-film transistor disposed in the non-display area NA and the display area AA, and aspects of the present disclosure are not limited to those described above.

The gate driving circuit may include a shift register and a level shifter.

As in the display apparatus according to an aspect of the present disclosure, the gate driving circuit may be implemented in the form of a Gate In Panel (GIP) and disposed directly on the substrate 101.

The gate driver 91 including the gate driving circuit may sequentially supply a scan signal of an on-voltage or an off-voltage to a plurality of gate lines.

The gate driver 91 according to an aspect of the present disclosure may be formed directly on the substrate 101 by using a polycrystalline semiconductor material as a semiconductor layer, or it may be formed by configuring a thin-film transistor as a C-MOS using a polycrystalline semiconductor material as a semiconductor layer and using an oxide material as an insulating layer.

For example, the oxide semiconductor material may include at least one of n IGZO (InGaZnO)-based oxide semiconductor material, an IZO (InZnO)-based oxide semiconductor material, an IGZTO (InGaZnSnO)-based oxide semiconductor material, an ITZO (InSnZnO)-based oxide semiconductor material, a FIZO (FeInZnO)-based oxide semiconductor material, a ZnO-based oxide semiconductor material, a SIZO (SiInZnO)-based oxide semiconductor material, and a ZnON (Zn-Oxynitride)-based oxide semiconductor material, but aspects of the present disclosure are not limited thereto.

The incorporation of the thin-film transistor with the oxide semiconductor layer and the thin-film transistor with the polycrystalline semiconductor layer may enable high electron mobility in the channel, resulting in high-resolution and low-power implementations.

The display apparatus 1 according to an aspect of the present disclosure may further include a data driver 95 including a data driving circuit. The data driving circuit may convert image data into an analog data voltage and supply it to a plurality of data lines when a certain gate line is opened by the gate driver 91 including the gate driving circuit. For example, the gate driver 91 may be disposed symmetrically on the left and right sides of the display area AA, and aspects of the present disclosure are not limited to those described above.

The plurality of gate lines GL disposed on the substrate 101 may include a plurality of scan lines and a plurality of emission control lines. The plurality of scan lines and the plurality of emission control lines may be wirings carrying different types of gate signals (e.g., scan signals, emission control signals) to gate nodes of different types of transistors (e.g., scan transistors, emission control transistors).

The gate driver 91 including the gate driving circuit may include a scan driving circuit that outputs scan signals to a plurality of scan lines, which is one type of gate line GL, and an emission driving circuit that outputs emission control signals to a plurality of emission control lines, which is another type of the gate line GL.

The display panel 100 according to an aspect of the present disclosure may further include a bending area BA where the substrate 101 is bent, and aspects of the present disclosure are not limited thereto. The bending area BA may be an area where the substrate 101 is bent. The substrate 101 may remain flat in areas other than the bending area BA. The data lines DL may be disposed to pass through the bending area BA, and multiple data lines DL may be disposed to connect with the data pads.

FIG. 7 is a cross-sectional view of the display panel taken along line B-B′ in FIG. 6 according to an aspect of the present disclosure.

While the following describes a display apparatus using an organic light emitting display as an example, other light emitting display apparatuses such as quantum dot light emitting display apparatuses may be included, and aspects of the present disclosure are not limited thereto.

The display panel 100 of the display apparatus 1 according to one aspect of the present disclosure may include a substrate 101, a thin-film transistor TF, a planarization layer 107, a light-emitting element 115, a bank 110, a pad 140, a dam 190, and a touch part 160.

For example, in the display area AA, the thin-film transistor TF, the light-emitting element 115, and various functional layers are located on the substrate 101. For example, various driving circuits (e.g., GIPs), electrodes, wirings, functional structures, etc. may be located on the substrate 101 in the non-displayed area NA.

The substrate 101 may support various components of the display apparatus. The substrate 101 may be formed of a transparent insulating material, such as an insulating material, for example, glass, plastic, or the like. The substrate (array substrate) may also be referred to as a concept that includes devices and functional layers formed on the substrate 101, such as switching TFTs (thin-film transistor), driving TFTs, light-emitting elements, protective films, and the like.

A buffer layer 103 may be located on the substrate 101. The buffer layer is a functional layer that protects the thin-film transistor (TFT) from impurities such as alkaline ions leaking from the substrate 101 or the underlying layers. The buffer layer 103 may be formed of silicon oxide (SiOx), silicon nitride (SiNx), or a multilayer thereof. The buffer layer 103 may include a multi-buffer and/or an active buffer. The thin-film transistor TF may be disposed on the substrate 101 or the buffer layer 103. The thin-film transistor may have a form in which a semiconductor layer (an active layer), a gate insulating layer, a gate electrode, an interlayer dielectric layer ILD, and source and drain electrodes are stacked sequentially. In an aspect, referring to FIG. 7, the thin-film transistor TF may be in the form of a gate electrode 104, a first insulating layer 105, a semiconductor layer 102, and source and drain electrodes 108 arranged sequentially.

For example, the semiconductor layer 102 may be made of polysilicon (p-Si), in which case a predetermined region may be doped with impurities. For example, the semiconductor layer 102 may also be made of amorphous silicon (a-Si). For example, the semiconductor layer 102 may include an oxide. Aspects of the present disclosure are not limited to those described above.

The gate electrode 104 may be formed of a variety of conductive materials, such as magnesium (Mg), aluminum (Al), nickel (Ni), chromium (Cr), molybdenum (Mo), tungsten (W), gold (Au), or alloys thereof.

The first insulating layer 105 and the interlayer dielectric layer ILD may be formed of an insulating material such as silicon oxide (SiOx), silicon nitride (SiNx), or the like, and may alternatively be formed of an insulating organic material or the like. For example, the first insulating layer 105 may be a gate insulating layer. A contact hole through which the source and drain regions are exposed may be formed by selective removal of the first insulating layer 105 and the interlayer dielectric layer ILD.

The source and drain electrodes 108 are formed as single or multiple layers of electrode material on the first insulating layer 105 or interlayer dielectric layer ILD. In an aspect, a passivation layer 109 made of an inorganic insulating material may cover the source and drain electrodes 108.

A planarization layer 107 may be located on the thin-film transistor TF. The planarization layer 107 may protect the thin-film transistor and may planarize the upper portion thereof. The planarization layer 107 may be made of various forms, such as an organic insulating film such as benzocyclobutene (BCB) or acryl, or an inorganic insulating film such as silicon nitride (SiNx) or silicon oxide (SiOx), and may be formed as a single layer or double or multiple layers, and so on. For example, the planarization layer 107 may be formed of an organic film such as an acrylic resin, an epoxy resin, a phenolic resin, a polyamide resin, a polyimide resin, or the like.

The light-emitting element 115 may have a first electrode 112, a light-emitting layer 114, and a second electrode 116 arranged sequentially. For example, the light-emitting element 115 may include the first electrode 112 formed on the planarization layer 107, the light-emitting layer 114 located on the first electrode 112, and the second electrode 116 located on the light-emitting layer 114.

The first electrode 112 is electrically connected to the drain electrode 108 of the driving thin-film transistor TF via a contact hole. For example, when the display apparatus is a top emission type, the first electrode 112 may be made of an opaque conductive material having a high reflectivity. For example, the first electrode 112 may be formed of silver (Ag), aluminum (Al), gold (Au), molybdenum (Mo), tungsten (W), chromium (Cr), or an alloy thereof. For example, the first electrode 112 may be an anode of an organic light-emitting diode. Aspects of the present disclosure are not limited to those described above.

The bank 110 may be formed in an area other than the light-emitting area. Thus, the bank 110 has a bank hole that exposes the first electrode 112 corresponding to the light-emitting area. The bank 110 may be made of an inorganic insulating material such as silicon nitride (SiNx) and silicon oxide (SiOx), or an organic insulating material such as BCB, acryl-based resin and polyimide-based resin.

The light-emitting layer 114 may be located on the first electrode 112 exposed by the bank 110. The light-emitting layer 114 may include a light-emitting layer, an electron implantation layer, an electron transport layer, a hole transport layer, a hole implantation layer, and the like. The light-emitting layer may be configured as a structure of a single light-emitting layer that emits a single light, or may be configured as a structure of a plurality of light-emitting layers that emit white light.

The light-emitting element 115 may include two or more light-emitting parts. The light-emitting parts may be represented as a stack, but are not limited to this terminology. Two or more light-emitting parts may include a first light-emitting part and a second light-emitting part. The first light-emitting part and the second light-emitting part may include a red light-emitting layer, a green light-emitting layer, and a blue light-emitting layer that emit red, green, and blue light for each sub-pixel. The two or more light-emitting layers included in the first light-emitting part and the second light-emitting part may be light-emitting layers that emit light of the same color. In other example, a first light-emitting layer included in the first light-emitting part may be a blue light-emitting layer, a sky blue light-emitting layer, a deep blue light-emitting layer, a blue light-emitting layer and a red light-emitting layer, a sky blue light-emitting layer and a red light-emitting layer, and a deep blue light-emitting layer and a red light-emitting layer, but aspects of the present disclosure are not limited to those described above. For example, a second light-emitting layer included in the second light-emitting part may be a combination of a yellow light-emitting layer, a yellow-green light-emitting layer, a green light-emitting layer, a yellow light-emitting layer and a red light-emitting layer, a yellow-green light-emitting layer and a red light-emitting layer, a green light-emitting layer and a red light-emitting layer, a yellow light-emitting layer, a yellow-green light-emitting layer, and a green light-emitting layer, a combination of a yellow light-emitting layer, a yellow-green light-emitting layer, a green light-emitting layer, and a red light-emitting layer, a combination of two yellow-green light-emitting layers and one green light-emitting layer, a combination of one yellow-green light-emitting layer and two green light-emitting layers, a combination of two yellow-green light-emitting layers, one green light-emitting layer, and a red light-emitting layer, and a combination of one yellow-green light-emitting layer, two green light-emitting layers, and a red light-emitting layer, but aspects of the present disclosure are not limited to those described. A charge generating layer may be configured between the first light-emitting part and the second light-emitting part. The charge generating layer may include an n-type charge generating layer and a p-type charge generating layer. Each of the first light-emitting part and the second light-emitting part may include one or more of a hole injection layer, a hole transport layer, a hole blocking layer, an electron blocking layer, an electron transport layer, and an electron injection layer, but aspects of the present disclosure are not limited to those described above.

Two or more light-emitting parts may include a first light-emitting part, a second light-emitting part, and a third light-emitting part. A first light-emitting layer included in the first light-emitting part may be the same as described above. A second light-emitting layer included in the second light-emitting part may be the same as described above. A third light-emitting layer included in the third light-emitting part may be configured in the same manner as the first light-emitting layer, and aspects of the present disclosure are not limited to those described above. A first charge generating layer may be configured between the first light-emitting part and the second light-emitting part. The first charge generating layer may include an n-type charge generating layer and a p-type charge generating layer. A second charge generating layer may be formed between the second light-emitting part and the third light-emitting part. The second charge generating layer may include an n-type charge generating layer and a p-type charge generating layer. Each of the first light-emitting part, the second light-emitting part, and the third light-emitting part may include one or more of a hole injection layer, a hole transport layer, a hole blocking layer, an electron blocking layer, an electron transport layer, and an electron injection layer, but aspects of the present disclosure are not limited to those described above.

Two or more light-emitting parts may include a first light-emitting part, a second light-emitting part, a third light-emitting part, and a fourth light-emitting part. At least two light-emitting layers of the first light-emitting part, the second light-emitting part, the third light-emitting part, and the fourth light-emitting part may be comprised of light-emitting layers that emit light of the same color. For example, at least two light-emitting layers of the first light-emitting part, the second light-emitting part, the third light-emitting part, and the fourth light-emitting part may be comprised of a blue light-emitting layer, but aspects of the present disclosure are not limited to those described above. At least one light-emitting layer of the first light-emitting part, the second light-emitting part, the third light-emitting part, and the fourth light-emitting part may comprise a light-emitting layer different from the blue light-emitting layer. For example, at least one light-emitting layer of the first light-emitting part, the second light-emitting part, the third light-emitting part, and the fourth light-emitting part may be a combination of a yellow light-emitting layer, a yellow-green light-emitting layer, a green light-emitting layer, a yellow light-emitting layer and a red light-emitting layer, a yellow-green light-emitting layer and a red light-emitting layer, a green light-emitting layer and a red light-emitting layer, a yellow light-emitting layer, a yellow-green light-emitting layer, and a green light-emitting layer, a combination of a yellow light-emitting layer, a yellow-green light-emitting layer, a green light-emitting layer, and a red light-emitting layer, a combination of two yellow-green light-emitting layers and one green light-emitting layer, a combination of one yellow-green light-emitting layer and two green light-emitting layers, a combination of two yellow-green light-emitting layers, one green light-emitting layer, and a red light-emitting layer, and a combination of one yellow-green light-emitting layer, two green light-emitting layers, and a red light-emitting layer, but aspects of the present disclosure are not limited to those described above. A first charge generating layer may be configured between the first light-emitting part and the second light-emitting part. The first charge generating layer may include an n-type charge generating layer and a p-type charge generating layer. A second charge generating layer may be formed between the second light-emitting part and the third light-emitting part. The second charge generating layer may include an n-type charge generating layer and a p-type charge generating layer. A third charge generating layer may be formed between the third light-emitting part and the fourth light-emitting part. The third charge generating layer may include an n-type charge generating layer and a p-type charge generating layer. Each of the first light-emitting part, the second light-emitting part, the third light-emitting part, and the fourth light-emitting part may include one or more of a hole injection layer, a hole transport layer, a hole blocking layer, an electron blocking layer, an electron transport layer, and an electron injection layer, but aspects of the present disclosure are not limited to those described above.

For example, the second electrode 116 is located on the light-emitting layer 114. When the organic light-emitting display apparatus is a top emission type, the second electrode 116 is formed of a transparent conductive material such as indium tin oxide (ITO) and indium zinc oxide (IZO) to emit light generated in the light-emitting layer 114 to the top portion of the second electrode 116. For example, the second electrode 116 may be a cathode of an organic light-emitting diode. Aspects of the present disclosure are not limited to those described above.

An encapsulation part 150 is disposed on the light-emitting element 115. The encapsulation part 150 is a sealing member that protects the light emitting material and the electrode material of the light-emitting element 115 from external moisture, oxygen, shock, and the like to prevent oxidation of the light-emitting material and the electrode material. The encapsulation part 150 may be disposed to cover the entirety of the display area AA in which the light-emitting element 115 is disposed, and the encapsulation part 150 may also be disposed to cover a portion of the non-display area NA extending from the display area AA. The encapsulation part 150 may include a first inorganic encapsulation layer 151 made of an inorganic material, an organic encapsulation layer 152 disposed on the first inorganic encapsulation layer 151 and made of an organic material, and a second inorganic encapsulation layer 153 disposed on the organic encapsulation layer 152, but aspects of the present disclosure are not limited to those described above.

The first inorganic encapsulation layer 151 seals the display area AA to protect the light-emitting element 115 from oxygen and moisture penetrating into the display area AA. The first inorganic encapsulation layer 151 may be disposed not only in the display area AA, but also in the non-display area NA extending from the display area AA, and may be disposed to cover the dam 190 in the non-display area NA. The first inorganic encapsulation layer 151 may be made of an inorganic material, for example, but not limited to, silicon nitride (SiNx), silicon oxide (SiOx), silicon oxynitride (SiON), or the like.

The organic encapsulation layer 152 is disposed on the first inorganic encapsulation layer 151. The organic encapsulation layer 152 may planarize the upper portion of the first inorganic encapsulation layer 151, may fill cracks that may occur in the first inorganic encapsulation layer 151, and may planarize the upper portion of a foreign material when the foreign material is formed on the first inorganic encapsulation layer 151. The organic encapsulation layer 152 may be disposed in the display area AA and may also be disposed in a portion of the non-display area NA extending from the display area AA, and may be disposed inwardly of the dam 190. The organic encapsulation layer 152 may be made of an epoxy-based polymer or an acrylic-based polymer, but is not limited thereto.

The second inorganic encapsulation layer 153 is disposed on the organic encapsulation layer 152. The second inorganic encapsulation layer 153 may seal the organic encapsulation layer 152 in combination with the first inorganic encapsulation layer 151 in such a manner that it abuts the first inorganic encapsulation layer 151 at the outer periphery of the display apparatus 1. The second inorganic encapsulation layer 153 may also be disposed in a portion of the non-display area NA extending from the display area AA, and the second inorganic encapsulation layer 153 may be disposed to abut the first inorganic encapsulation layer 151 disposed in the non-display area NA. The second inorganic encapsulation layer 153 may be made of an inorganic material, for example, but not limited to, silicon nitride (SiNx), silicon oxide (SiOx), silicon oxynitride (SiON), or the like.

Although FIG. 7 shows that the encapsulation part 150 includes the first inorganic encapsulation layer 151, the organic encapsulation layer 152, and the second inorganic encapsulation layer 153, the number of the inorganic encapsulation layers and the organic encapsulation layers included in the encapsulation part 150 are not limited thereto.

For example, the substrate 101 and the organic/inorganic layers 105, 107, and 120 and the like may exist in the non-display area NA. For example, in the non-display area NA, the materials used in the construction of the display area AA may be disposed in the same layer for different purposes. For example, the same metal 104′ as the gate electrode 104 of the thin-film transistor TF in the display area AA, or the same metal 108′ as the source/drain electrode, may be disposed in the non-display area NA for wiring or electrodes. In an aspect, the same metal 112′ as one electrode (e.g., anode) of the organic light-emitting diode may be disposed in the non-display area NA for wirings or electrodes.

The substrate 101, the buffer layer 103, the first insulating layer 105, the planarization layer 107, and the like in the non-display area NA may be the same as described in the display area AA. For example, the dam 190 may be disposed in the non-display area NA on the substrate 101. The dam 190 is disposed to control the spread of the organic encapsulation layer 152 of the encapsulation part 150 that is disposed to cover the display area AA. For example, the dam 190 may suppress the overflow of the organic encapsulation layer 152 of the encapsulation part 150. The dam 190 may consist of one or more dams, but there is no limit to the number of dams to be deployed.

Various circuits and electrodes/electrical wires that are disposed in the non-display area NA may be made of a gate metal 104′ and/or a source/drain metal 108′. In this case, the gate metal 104′ may be formed of the same material as the gate electrode of the TFT in the same process, and the source/drain metal 108′ may be formed of the same material as the source/drain electrode of the TFT in the same process.

For example, the source/drain metal may be used as the wiring 108′ for a power source (e.g., a base power source (VSS)). In this case, the power source wiring 108′ may be connected to the metal layer 112′, and the second electrode 116 of the light-emitting diode may be powered through the connection with the source/drain metal 108′ and the metal layer 112′. The metal layer 112′ may contact the power wiring 108′ and may extend along the outermost sidewall of the planarization layer 107 to contact the second electrode 116 at the upper portion of the planarization layer 107. For example, the metal layer 112′ may be a metal layer formed of the same material on the same layer and in the same process as the first electrode 112 of the organic light-emitting diode. Aspects of the present disclosure are not limited to those described above.

The pad 140 may be disposed in the non-display area NA. The pad 140 may be disposed on an outer side of the dam 190. A signal may be input to a circuit part, a driving chip (circuit chip), and the like formed on the substrate 101 through the pad 140. For example, the pad 140 may supply an externally supplied signal to the circuit part of the substrate 101, the driving chip (circuit chip), and the like. For example, the pad 140 may supply signals to a touch part 160 to drive the touch part 160, and may receive signals from the touch part 160 in response to a user's touch input.

In an aspect, the touch part 160 may be disposed on the encapsulation part 150. Aspects of the present disclosure are not limited to those described above. The touch part 160 may be disposed in the display area AA including the light-emitting element 115 to sense the touch input. The touch part 160 may detect external touch information, such as from a user's finger or a touch pen. The touch part 160 may include a first protective layer 161, a second protective layer 162, an organic insulating layer 167, a first touch electrode 164, and a second touch electrode 165.

The first protective layer 161 may be disposed on the encapsulation part 150. The first protective layer 161 may contact the second inorganic encapsulation layer 153 of the encapsulation part 150. The first protective layer 161 may be made of an inorganic material. For example, it may be made of an inorganic material such as silicon nitride (SiNx), silicon oxide (SiOx), and silicon oxynitride (SiONx), and the like, but an aspect of the present disclosure is not limited thereto.

The first touch electrode 164 is disposed on the first protective layer 161. The first touch electrode 164 is disposed on the first protective layer 161 in the display area (AA). Each of the first touch electrodes 164 may be spaced apart from each other and disposed in the X-axis direction and the Y-axis direction. For example, the first touch electrodes 164 may include a plurality of patterns arranged in the X-axis direction and a plurality of patterns arranged in the Y-axis direction that are spaced apart. For example, the X-axis direction may be in the second direction, and the Y-axis direction may be in the first direction, but the directions are not necessarily limited thereto. The first touch electrode 164 supplies a touch driving signal to drive the touch part 160. In addition, the first touch electrode 164 may transmit touch information sensed by the touch part 160 to the driving IC. The first touch electrode 164 may be, but is not limited to, in the form of a mesh. The first touch electrode 164 may be made of, but is not limited to, a metallic material.

The second protective layer 162 may be disposed on the first touch electrode 164 and the first protective layer 161. The second protective layer 162 may prevent the adjacent first touch electrode 164 from being short-circuited.

The second touch electrode 165 is disposed on the second protective layer 162. The second protective layer 162 may be made of an inorganic material. For example, it may be made of an inorganic material such as, but not limited to, silicon nitride (SiNx), silicon oxide (SiOx), silicon oxynitride (SiONx), and the like.

In an aspect, an organic insulating layer 167 may be disposed on the second touch electrode 165. The organic insulating layer 167 may be made of at least one of the following organic insulating materials: acrylic resin, epoxy resin, phenolic resin, polyamide resin, or polyimide resin, but aspects herein are not limited to those described above.

The pad 140 and the second touch electrode 165 may be electrically connected to the circuit film 400 via a conductive adhesive layer 395.

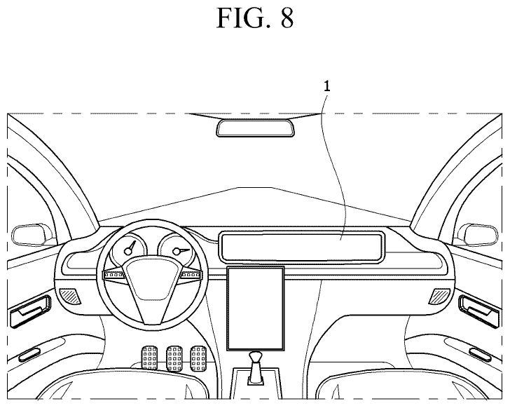

FIG. 8 is a diagram illustrating an application of a display apparatus according to one aspect of the present disclosure, for example, a form in which the display apparatus is provided inside a vehicle.

As shown in FIG. 8, the display apparatus 1 may be disposed on at least a portion of a dashboard of the vehicle. The dashboard of the vehicle includes a configuration disposed in front of a front seat (e.g., driver seat, passenger seat) of the vehicle. For example, the dashboard of the vehicle may have input configurations for manipulating various features (e.g., an air conditioner, an audio system, a navigation system) in the vehicle.

In an aspect, the display apparatus 1 may be disposed on the dashboard of the vehicle and operate as an input part to manipulate at least some of the various features of the vehicle. The display apparatus 1 may provide various information related to the vehicle, such as information about the operation of the vehicle (e.g., the current speed of the vehicle, the amount of remaining fuel, mileage), information about parts of the vehicle (e.g., the degree of damage to the vehicle tire).

In an aspect, the display apparatus 1 may be arranged to cross a driver's seat and a passenger seat arranged in the front seat of the vehicle. A user of the display apparatus 1 may be a vehicle driver and a passenger in the passenger seat. Both the driver and the passenger of the vehicle may use the display apparatus 1.

In an aspect, the display apparatus 1 as illustrated in FIG. 8 is shown only in part. The display apparatus 1 as illustrated in FIG. 8 may represent a display panel among various components that may be included in the display apparatus 1. Among the components of the display apparatus 1, components other than those illustrated in FIG. 8 may be mounted within (or at least within a portion) of the vehicle.

The display apparatus mounted on a vehicle is an example for describing the present disclosure, and an aspect herein is not limited thereto.

The display apparatus according to an aspect of the present disclosure may be applicable to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation device, an in-vehicle navigation device, an in-vehicle display apparatus, an in-vehicle device, theater device, theater display apparatus, a television, a wallpaper device, a signage device, a gaming device, a laptop, a monitor, a camera, a camcorder, and a home appliance. Further, the display apparatus of the present disclosure may be applicable to an organic light-emitting lighting device or an inorganic light-emitting lighting device.

The display apparatus according to an aspect of the present disclosure may be described as follows.

A display apparatus according to an aspect of the present disclosure may include a plate; a display panel disposed on the plate; a printed circuit board disposed below the plate; and a circuit film configured to electrically connect the display panel and the printed circuit board, wherein the plate includes an extension part that is bent in a manner corresponding to the bending of the circuit film.

According to some aspects of the present disclosure, the extension part of the plate may be bent from one side of the plate toward a rear surface of the display panel.

According to some aspects of the present disclosure, the display apparatus may further comprise a driving chip on the rear surface of the display panel, wherein the driving chip may be disposed between the circuit film and the extension part of the plate.

According to some aspects of the present disclosure, the plate may include an upper layer and a lower layer, and the upper layer may be disposed on the lower layer.

According to some aspects of the present disclosure, the driving chip may be disposed between the lower layer of the plate and the circuit film.

According to some aspects of the present disclosure, the plate may be hemmed so that at least a portion of the lower layer faces at least a portion of the upper layer.

According to some aspects of the present disclosure, a cushion member may be further disposed between the upper layer and the lower layer of the plate.

According to some aspects of the present disclosure, the cushion member may include a foam and an adhesive member, and the plate and the foam are fixed using the adhesive member.

According to some aspects of the present disclosure, the extension part of the plate may be in contact with an end of the printed circuit board to allow the printed circuit board to be fixed in a first orientation.

According to some aspects of the present disclosure, an end of the plate may be bent at an area where the extension part of the plate contacts the end of the printed circuit board.

According to some aspects of the present disclosure, the plate may further include a protrusion, and the protrusion of the plate may be configured to fix the printed circuit board in a second direction.

According to some aspects of the present disclosure, at least one extension part of the plate may comprise a plurality of extension parts, which are spaced apart from each other.

According to some aspects of the present disclosure, a pad may be disposed in a non-display area of the display panel, and the pad is electrically connected to the circuit film via a conductive adhesive layer.

According to some aspects of the present disclosure, the display panel may further include a touch electrode, and the display panel may be electrically connected to the circuit film via the touch electrode and the conductive adhesive layer.

According to some aspects of the present disclosure, a material of the plate may be different from a material of the circuit film, and a thickness of the plate may be different from a thickness of the circuit film.

According to some aspects of the present disclosure, the circuit film may include polyimide, and the plate may include any one of aluminum, copper, and graphite.

A display apparatus according to an aspect of the present disclosure may include a plate; a display panel disposed on the plate; a printed circuit board electrically connected to one side of the display panel; and at least one circuit film, a portion of which is bent, electrically connected to the printed circuit board, wherein the plate may include an upper layer and a lower layer, the upper layer may be disposed on the lower layer, and a driving chip may be disposed between the lower layer of the plate and the circuit film.

According to some aspects of the present disclosure, the plate may include at least one extension part protruding from a side surface of the display panel.

According to some aspects of the present disclosure, the plate may have different heights in a center region that overlaps the display area and an end region that overlaps the non-display area.

According to some aspects of the present disclosure, at least a portion of the extension part contacts at least a portion of the printed circuit board.

According to some aspects of the present disclosure, the display apparatus may further comprise a bent portion formed by bending an end of the extension part, wherein the bent portion may be in contact with the circuit film.

According to some aspects of the present disclosure, the display apparatus may further comprise a cushion member attached to the rear surface of the plate, wherein at least a portion of the cushion member may contact the extension part.

According to some aspects of the present disclosure, the display apparatus may further comprise a driving chip disposed on the circuit film, wherein the driving chip may be disposed opposite the extension part.

Although the aspects of the present disclosure have been described in more detail with reference to the accompanying drawings, the present disclosure is not limited thereto and may be embodied in many different forms without departing from the technical concept of the present disclosure. Therefore, the aspects disclosed in the present disclosure are provided for illustrative purposes only and are not intended to limit the technical concept of the present disclosure. The scope of the technical concept of the present disclosure is not limited thereto. Therefore, it should be understood that the above-described aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus comprising:
a plate;
a display panel disposed on the plate;
a printed circuit board disposed below the plate; and
a circuit film configured to electrically connect the display panel and the printed circuit board,
wherein the plate includes an extension part being bent to correspond to a bending portion of the circuit film.

2. The display apparatus of claim 1, wherein the extension part of the plate is bent from one side of the plate toward a rear surface of the display panel.

3. The display apparatus of claim 1, further comprising a driving chip disposed on the rear surface of the display panel,
wherein the driving chip is disposed between the circuit film and the extension part of the plate.

4. The display apparatus of claim 3, wherein the plate includes an upper layer and a lower layer, and
wherein the upper layer is disposed on the lower layer.

5. The display apparatus of claim 4, wherein the driving chip is disposed between the lower layer of the plate and the circuit film.

6. The display apparatus of claim 4, wherein the plate is hemmed so that at least a portion of the lower layer faces at least a portion of the upper layer.

7. The display apparatus of claim 6, wherein an end of the lower layer of the plate is in contact with at least a portion of the upper layer.

8. The display apparatus of claim 4, further comprising a cushion member disposed between the upper layer and the lower layer of the plate.

9. The display apparatus of claim 8, wherein the cushion member includes a foam and an adhesive member, and
wherein the plate and the foam are fixed using the adhesive member.

10. The display apparatus of claim 1, wherein the extension part of the plate is in contact with an end of the printed circuit board to allow the printed circuit board to be fixed in a first orientation.

11. The display apparatus of claim 10, wherein an end of the plate is bent at an area where the extension part of the plate contacts the end of the printed circuit board.

12. The display apparatus of claim 1, wherein the plate further includes a protrusion configured to fix the printed circuit board in a second direction.

13. The display apparatus of claim 1, wherein at least one extension part of the plate comprises a plurality of extension parts, which are spaced apart from each other.

14. The display apparatus of claim 1, further comprising a pad disposed in a non-display area of the display panel,
wherein the pad is electrically connected to the circuit film via a conductive adhesive layer.

15. The display apparatus of claim 14, further comprising a touch electrode disposed in the display panel,
wherein the display panel is electrically connected to the circuit film via the touch electrode and the conductive adhesive layer.

16. The display apparatus of claim 1, wherein a material of the plate is different from a material of the circuit film, and
wherein a thickness of the plate is different from a thickness of the circuit film.

17. The display apparatus of claim 1, wherein the circuit film includes polyimide, and
wherein the plate includes one of aluminum, copper, and graphite.

18. A display apparatus comprising:
a plate;
a display panel disposed on the plate;
a printed circuit board electrically connected to one side of the display panel;
at least one circuit film, a portion of which is bent, electrically connected to the printed circuit board,
wherein the plate includes an upper layer and a lower layer, and the upper layer is disposed on the lower layer; and
a driving chip disposed between the lower layer of the plate and the circuit film.

19. The display apparatus of claim 18, wherein the plate includes at least one extension part protruding from a side surface of the display panel.

20. The display apparatus of claim 18, wherein the plate includes a protrusion in an area where the plate overlaps an end of the printed circuit board.

21. A display apparatus comprising:
a plate;
a display panel disposed on the plate;
a printed circuit board electrically connected to one side of the display panel; and
at least one circuit film having one side and another side respectively electrically connected to the display panel and the printed circuit board, at least a portion of which is bent toward a rear surface of the display panel,
wherein at least a portion of the plate includes at least one extension part that is configured to overlap the circuit film on a rear surface of the circuit film and to protrude from a side surface of the display panel.

22. The display apparatus of claim 21, wherein at least a portion of the extension part contacts at least a portion of the printed circuit board.

23. The display apparatus of claim 22, further comprising a bent portion formed by bending an end of the extension part,
wherein the bent portion is in contact with the circuit film.

24. The display apparatus of claim 22, wherein the plate further includes two protrusions protruding from a rear surface of the plate, and
wherein the printed circuit board is located between the two protrusions.

25. The display apparatus of claim 24, further comprising a cushion member attached to the rear surface of the plate,
wherein at least a portion of the cushion member contacts the extension part.

26. The display apparatus of claim 21, further comprising a driving chip disposed on the circuit film,
wherein the driving chip is disposed opposite to the extension part.

27. A display apparatus comprising:
a display panel;
a plate disposed at a rear surface of the display;
a printed circuit board disposed a rear surface of the plate; and
a circuit film having one side electrically connected to one side of the display panel and another side electrode connected to the printed circuit board,
wherein the plate includes an extension part that is bent toward the printed circuit board, and extends from an end of the plate close to the one side of the display panel to a position of the rear surface of the plate close to the circuit board, and
wherein at least a part of the circuit film extends along the extension part of the plate and is supported by the extension part.

28. The display apparatus of claim 27, wherein the plate is a metal sheet or a graphite sheet and has a bent shape.
